(19) United States
(12) Patent Application Publication
(10) Pub. No.: US 2026/0251731 A1
(43) Pub. Date: Aug. 27, 2026

(54) METHOD AND SYSTEM FOR FIELD CALIBRATION OPERATIONAL BANDWIDTH AND NOISE LEVEL OF LARGE-SCALE MAGNETIC SENSOR

(71) Applicant: Aerospace Information Research Institute, Chinese Academy of Sciences, Beijing (CN)

(72) Inventors: Jiankai LI, Beijing (CN); Guangyou FANG, Beijing (CN); Ling HUANG, Beijing (CN); Lihua LI, Beijing (CN); Xiaojun LIU, Beijing (CN); Jiangjie HUANG, Beijing (CN)

(21) Appl. No.: 19/463,853

(22) Filed: Jan. 29, 2026

(30) Foreign Application Priority Data
Feb. 21, 2025 (CN) 202510195147.9

(51) Int. Cl. G01R 33/00

(52) U.S. Cl. CPC G01R 33/0017

(57) ABSTRACT

Conventional calibration fixtures, such as Helmholtz coils and magnetically shielded rooms, are incapable of accommodating large-scale magnetic sensors with coil diameters of 2 meters or more, preventing accurate quantification of their operational bandwidth and noise level. The present invention provides a method and system for performing such calibration in an open, field environment, overcoming these physical constraints. The method involves deploying a large-scale calibration coil on the ground. To calibrate the operational bandwidth, a reference magnetic sensor with a known conversion coefficient and the large-scale sensor under test are simultaneously exposed to a magnetic field generated by the calibration coil. Their output signals are synchronously acquired via a multi-channel receiver and compared to determine the conversion coefficient of the sensor under test. To determine the intrinsic noise level, the large-scale sensor under test and a second sensor of the same type are simultaneously exposed to the generated magnetic field. A correlation analysis is performed on their synchronously acquired output signals to to determine a noise level of the magnetic sensor under test. This invention enables high-precision, quantitative calibration of oversized magnetic sensors, which is critical for applications such as airborne electromagnetic detection systems.

### BACKGROUND

### Technical Field

The present invention pertains generally to the technical field of magnetic sensor calibration. More specifically, it relates to high-precision methods and systems for calibrating the operational bandwidth and noise level of large-scale magnetic sensors used in geophysical exploration applications, including but not limited to airborne electromagnetic detection systems.

### Description of the Related Art

Magnetic sensors are critical components in geophysical electromagnetic detection systems, such as those used for mineral exploration and groundwater assessment. The quality of the data these systems produce is heavily dependent on the performance of the magnetic sensors, particularly their operational bandwidth and intrinsic noise level. Therefore, accurate calibration of these parameters is essential. Conventional calibration methods, however, face significant and fundamental limitations when applied to large-scale sensors with coil diameters of 2 meters or more.

Limitations in Bandwidth Calibration of Large-Scale Sensors: The operational bandwidth of magnetic sensors is conventionally evaluated by the sensitivity of magnetic field conversion, and typically calibrated using fixtures such as s“uniform magnetic field solenoid coil” or “Helmholtz coil” (collectively referred to as “calibration coils”). These fixtures generate a defined, uniform magnetic field when fed with a known alternating current. The operational bandwidth of the magnetic sensor is subsequently determined by acquiring the signal from the magnetic sensor placed inside the this uniform region of the calibration coil and analyzing the conversion coefficient across frequencies of the magnetic sensor (typically a frequency-dependent curve, i.e., the magnetic field conversion sensitivity curve). However, a fundamental limitation of these conventional calibration coils (the existing “uniform magnetic field solenoid coil” or “Helmholtz coil”) is their restricted volume of uniform magnetic field. Typically, the physical size of such coils is less than 2 meters in diameter, and the effective uniform field region is even smaller. This physical constraint renders them fundamentally incapable of accommodating or providing a uniform calibration field for large-scale magnetic sensors with coil diameters exceeding several meters, such as those used in airborne electromagnetic detection systems. Consequently, quantitative testing and calibration of the operational bandwidth for these oversized sensors using traditional means have been unachievable with high accuracy.

Limitations in Noise Level Testing of Large-Scale Sensors: Similarly, measuring the intrinsic noise level requires isolating the sensor from ambient electromagnetic noise, typically achieved within magnetically shielded rooms (MSRs). Standard low-frequency MSRs provide excellent shielding but have very limited internal dimensions, typically less than 2 m×2 m×2 m (length×width×height), making them physically incapable of housing large-scale sensors.

While larger shielded enclosures do exist, they are generally designed as high-frequency electromagnetic anechoic chambers for radio-frequency testing and provide negligible attenuation of the low-frequency magnetic noise that is critical for sensors used in geophysical exploration. Therefore, no practical shielded environment exists for conducting high-precision noise level tests on large-scale, low-frequency magnetic sensors, especially those requiring femtotesla-level sensitivity.

In summary, the existing infrastructure for sensor calibration is fundamentally constrained by physical size limitations. There is a clear absence in the art of a method or system capable of accurately quantifying both the operational bandwidth and the intrinsic noise level of large-scale magnetic sensors outside the confines of laboratory-scale calibration coils and magnetically shielded rooms.

### BRIEF SUMMARY

The present invention provides a method and system for field calibration of the operational bandwidth and noise level of a large-scale magnetic sensor. It is specifically designed to overcome the fundamental physical limitations of conventional calibration fixtures, such as Helmholtz coils and magnetically shielded rooms, which are incapable of accommodating sensors with a coil diameter of 2 meters or more.

The inventive method comprises three principal steps that leverage a large-scale, ground-deployed transmitting current coil acting as a calibration coil to generate a controlled magnetic field in an open environment.

### Step 1: System Configuration.

A test site with a large operating space and a favorable electromagnetic environment is selected. A transmitting current coil, with a diameter typically ranging from 20 to 200 meters, is deployed on the ground to serve as the calibration coil. The configuration is chosen to accommodate the specific large-scale magnetic sensor under test.

### Step 2: Operational Bandwidth Calibration.

This step involves calibrating the magnetic field-to-voltage conversion coefficient of the magnetic sensor under test. A reference magnetic sensor, with a known and satisfactory conversion coefficient (e.g., a small-scale sensor pre-calibrated by conventional means), is placed relative to the magnetic sensor under test such that both are subjected to the same magnetic field generated by the calibration coil. An alternating current of varying frequencies is fed into the calibration coil. The voltage signals from both the reference sensor and the magnetic sensor under test are synchronously acquired by a multi-channel receiver. The operational bandwidth of the magnetic sensor under test is then determined by comparing its output to that of the reference sensor across the frequency spectrum, effectively transferring the calibration standard from the small reference sensor to the large magnetic sensor under test. The test can be configured using a concentric loop configuration or a dipole loop configuration to ensure magnetic field uniformity at the sensor locations.

### Step 3: Intrinsic Noise Level Calibration.

This step employs a correlation technique to isolate the intrinsic noise of the SUT from the ambient magnetic field signal. The magnetic sensor under test and a second magnetic sensor of the same type are placed in parallel within the generated field. The same magnetic field signal acts upon both sensors. Their output signals, each containing the coherent ambient signal plus the sensors' respective uncorrelated self-noise, are synchronously recorded. Correlation analysis (specifically, the difference between the auto-correlation and cross-correlation functions of the measured signals) is then performed to extract the power spectral density of the magnetic sensor under test's intrinsic noise, yielding a quantitative measure of its noise level.

In a second aspect, the present invention provides a system for calibrating an operational bandwidth and a noise level of a large-scale magnetic sensor, the system comprising:
a calibration coil, configured to be deployed in a test environment and to generate a magnetic field when driven by an alternating current source, wherein the calibration coil has a diameter of not less than 20 meters;
a multi-channel receiver; and
a processor, communicatively coupled to the multi-channel receiver and configured to:
(i) calibrate the operational bandwidth of the magnetic sensor under test based on voltage signals synchronously acquired by the multi-channel receiver from a reference magnetic sensor and the magnetic sensor under test when both are exposed to the magnetic field generated by the calibration coil; and
(ii) determine the noise level of the magnetic sensor under test by performing a correlation analysis on output signals synchronously acquired by the multi-channel receiver from the magnetic sensor under test and a second magnetic sensor of the same type when both are exposed to the magnetic field;
wherein the magnetic sensor under test is a large-scale magnetic sensor with a coil diameter not less than 2 meters.

In a third aspect, the present invention provides an electronic device. The electronic device comprises:
one or more processors; and
a memory configured for storing one or more programs;
wherein the one or more programs, when executed by the one or more processors, cause the one or more processors to implement the method for calibrating the operational bandwidth and the noise level of the large-scale magnetic sensor according to any one of the preceding claims.

In a fourth aspect, the present invention provides a non-transitory computer-readable storage medium. The storage medium has stored thereon executable instructions which, when executed by a processor, cause the processor to implement the method for calibrating the operational bandwidth and the noise level of the large-scale magnetic sensor according to any one of the preceding claims.

The present invention effectively solves the long-standing problem of quantitatively calibrating the operational bandwidth (including the conversion coefficient) and the noise level of oversized, low-noise magnetic sensors. It provides a viable and high-precision solution for performance evaluation and optimization of sensors used in critical applications such as airborne electromagnetic detection systems for geological survey and mineral exploration.

### BRIEF DESCRIPTION OF THE SEVERAL VIEWS OF THE DRAWINGS

FIG. 1 is a flowchart illustrating the overall method for calibrating the operational bandwidth and noise level of a large-scale magnetic sensor, in accordance with an embodiment of the present invention;

FIG. 2 is a schematic diagram of a concentric loop configuration for calibrating the conversion coefficient (operational bandwidth) of a large-scale magnetic sensor;

FIG. 3 is a schematic diagram of a dipole loop configuration for calibrating the conversion coefficient (operational bandwidth) of a large-scale magnetic sensor;

FIG. 4 is a schematic diagram illustrating the principle of noise level calibration for a large-scale magnetic sensor;

FIG. 5 is a graph showing conversion factor versus frequency for a large-scale magnetic sensor,, obtained from an embodiment of the present invention.;

FIG. 6 is another graph showing conversion factor versus frequency for a large-scale magnetic sensor under different test conditions, obtained from an embodiment of the present invention; and

FIG. 7 is a graph showing the power spectral density of the output voltage from a noise level test, illustrating the intrinsic noise floor of a large-scale magnetic sensor, in accordance with an embodiment of the present invention.

### DETAILED DESCRIPTION

The present invention will now be described in further detail with reference to the accompanying drawings and embodiments.

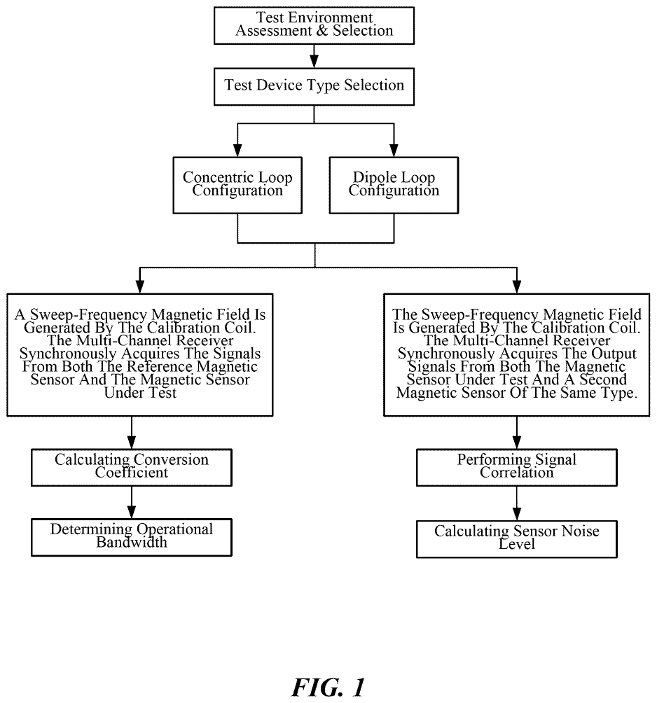

To address the problem that that conventional methods cannot test the high-precision performance indices (operational bandwidth and noise level) of large-scale, low-noise magnetic sensors, the present invention provides a method and system for their calibration. A flowchart of the method is shown in FIG. 1. This solution enables the quantitative testing and calibration of these two key performance indicators, solving the problem of quantitatively calibrating large-scale sensors. The present invention is applicable to performance testing and calibration of large-scaled magnetic field sensors in systems such as geophysical electromagnetic detection equipment. Based on the above-mentioned arrangement, each step of the present invention is described as follows.

### Step 1: System Configuration.

A test environment and a test device type are selected. A transmitting current coil is deployed in the test environment to serve as a calibration coil. The test device type is configured to accommodate both the calibration coil and the magnetic sensor under test.

The operational bandwidth of a magnetic sensor is evaluated by testing its conversion coefficient curve, which characterizes the conversion of an external magnetic field amplitude into an output voltage amplitude. The proposed test scheme requires two key elements:
1. A standard, small-size reference magnetic sensor (S₀), whose conversion coefficient is pre-calibrated and known, and whose operational bandwidth covers that of the large-scale sensor to be tested. The conversion coefficient of S₀ can be determined using conventional methods, such as those employing a “uniform magnetic field solenoid coil” or a “Helmholtz coil”. Sensor S₀ may be a coil-type sensor or a magnetic bar with a diameter of less than 2 meters.

A standard small-size magnetic sensor S₀ with its conversion coefficient known has the operational bandwidth of which basically covers the large-scale magnetic sensor S₁ to be tested, and the magnetic sensor to be calibrated and measured is a large-scale sensor. The conversion factor of the small-size magnetic sensor S₀ can be obtained by using a conventional test and calibration method based on a “uniform magnetic field solenoid coil” or a “Helmholtz coil”. Here, as a distinction, the standard small-size magnetic sensor S₀ includes a coil-type magnetic sensor or a magnetic bar. The coil-type magnetic sensor has a diameter of less than 2 meters,
2. The large-scale magnetic sensor under test S₁, which has a coil diameter of 2 meters or more. A field environment with a large operating space and a favorable electromagnetic background is selected to minimize complex interference in the test work. The operating space in the field environment must accommodate the deployment of a large-scale calibration coil (the transmitting current coil) on the ground, with a diameter typically ranging from 20 to 200 meters, selected based on the required test frequency band.

### Step 2: Operational Bandwidth Calibration.

An alternating current is input to the calibration coil to generate a magnetic field signal. This field simultaneously acts upon the reference sensor S₀ and the sensor under test S₁. The voltage signals from both sensors are synchronously acquired by a multi-channel receiver, and the operational bandwidth of S₁ is calibrated based on these signals.

The operational bandwidth calibration procedure is as follows:

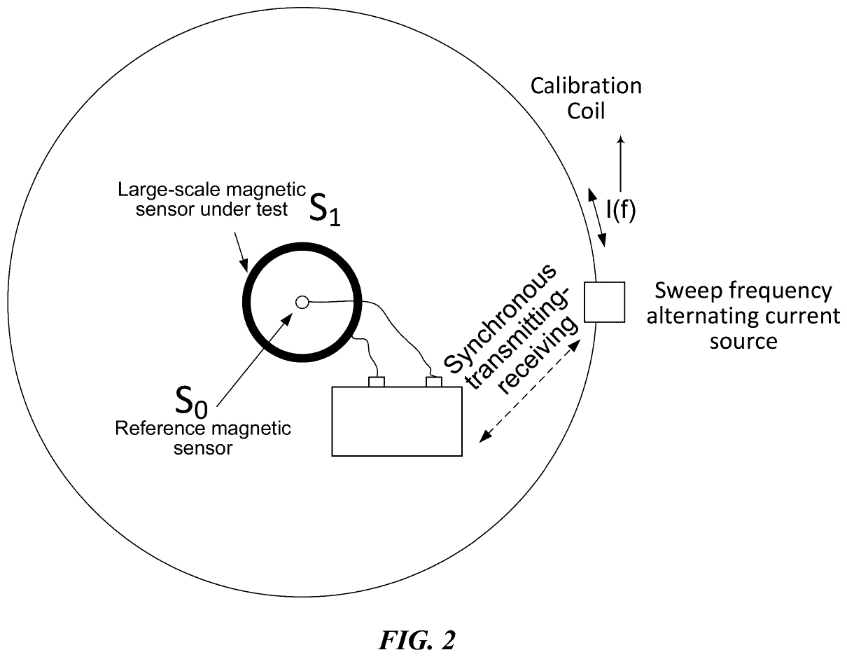

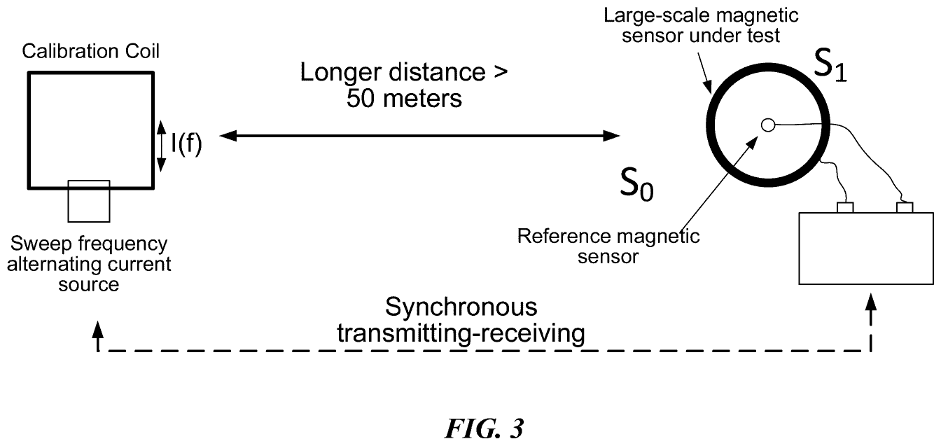

Firstly, the reference sensor S₀ and the sensor under test S₁ are placed simultaneously either at the center of the calibration coil (i.e., the concentric loop configuration shown in FIG. 2) or at a remote location from the coil (i.e., the dipole loop configuration shown in FIG. 3). The calibration coil is a transmitting current coil.

Secondly, an alternating current generator feeds currents of different frequencies into the calibration coil, generating a magnetic field signal with sufficient amplitude to suppress environmental and sensor self-noise. This ensures a high signal-to-noise ratio for both S₀ and S₁.

Then, a dual-channel signal receiver synchronously acquires the voltage signals from S₀ and S₁. These signals result from the respective sensors converting the ambient magnetic field using their own conversion coefficients.

To ensure magnetic field uniformity at the sensor locations: For the concentric loop configuration in FIG. 2, a large diameter calibration coil is used. For the dipole loop configuration in FIG. 3, a large dipole moment (typically requiring a distance greater than 50 meters from the coil to the sensors, as exemplified in FIG. 3) is used. Under these conditions, the magnetic field strength incident on both S₀ and S₁ sensors is equal:

$${H}_{0} ( nT ) = {H}_{1} ( nT )$$

where H denotes magnetic field strength (H₀ and H₁ for magnetic sensors S₀ and S₁ respectively), and nT is the unit (nanotesla) of magnetic field strength.

In order to obtain the conversion coefficient of the large-scale magnetic sensor S₁, the response of the large-scale magnetic sensor S₁ is calibrated by the received response of the small-size magnetic sensor S₀, and then the operational bandwidth of the large-scale magnetic sensor S₁ is analyzed.

To determine the conversion coefficient of S₁, its response is calibrated against the known response of S₀. For a given frequency, let U₁(mV) be the output amplitude of S₁, and U₀(mV) be the output amplitude of S₀, whose conversion coefficient is TF_{S}_{₀}(mV/nT).

The conversion coefficient TF_{S}_{₁}(mV/nT) of S₁ is calculated as follows:

$${H}_{0} ( nT ) = \frac{{U}_{0} ( mV )}{{TF}_{{S}_{0}} ( mV / nT )} ,$$

$${H}_{1} ( nT ) = \frac{{U}_{1} ( mV )}{{TF}_{{S}_{1}} ( mV / nT )} ,$$

$$Since {H}_{0} ( nT ) = {H}_{1} ( nT ) , solving for {TF}_{{S}_{1}} yields :$$

$${TF}_{{S}_{1}} ( mV / nT ) = \frac{{U}_{1} ( mV )}{\frac{{U}_{0} ( mV )}{{TF}_{{S}_{0}} ( mV / nT )}} .$$

Finally, by by measuring TF_{S}_{₁} across different frequencies, the operational bandwidth of S₁ can be determined from its frequency response.

### Step 3: Intrinsic Noise Level Calibration.

An alternating current is input to the calibration coil, generating a magnetic field that acts simultaneously on the sensor under test S₁ and a second magnetic sensor of the same type S′₁ of the same model., The output signals from both sensors are synchronously acquired by the multi-channel receiver, and the correlation analysis is performed to determine the intrinsic noise level of S₁.

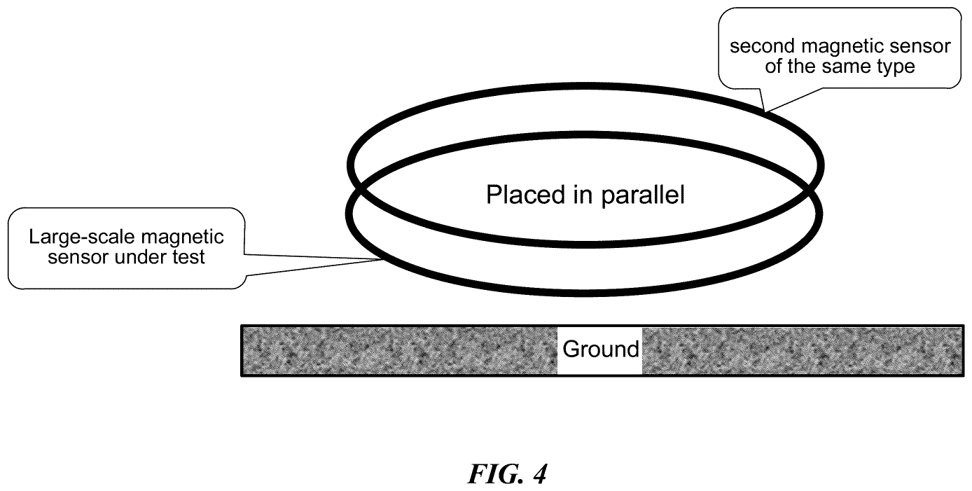

This step employs a parallel noise test method based on coherent signal processing. The principle is illustrated in FIG. 4. Sensors S₁ and S′₁ are placed parallel to each other on the ground, with their coils arranged vertically spaced and non-coplanar to minimize mutual interference while ensuring exposure to the same magnetic field.

The specific steps of noise level test are as follows.

Firstly, an environment far away from strong interference and near-field electromagnetic noise source is selected. Two large-scale magnetic sensors of the same model are used to conduct a noise level test by the parallel test method. The test principle is as shown in FIG. 4. The large-scale magnetic sensor S₁ under test and the second magnetic sensor of the same type S′₁ are placed parallel on the ground. These sensors are highly consistent coils of the same model and technology, arranged vertically spaced and non-coplanar to eliminate mutual interference while ensuring exposure to the same magnetic field.

Secondly, the large-scale calibration coil is deployed using either the concentric loop (FIG. 2) or dipole loop (FIG. 3) configuration. An alternating current source feeds currents of different frequencies (selected based on the target calibration band) into the calibration coil. The multi-channel receiver synchronously acquires the output signals from S′₁ and S₁.

Theoretically, two co-axial or co-planar magnetic sensor coils placed close to each other in a same uniform magnetic field can receive the same strength, synchronous, and coherent ambient magnetic field signals S(t). In addition to the ambient magnetic field signal, the output signals of the magnetic sensor coil also contain its own self-noise. The signals measured synchronously from the two parallel sensor coils S₁ and S′₁ are expressed as:

$${U}_{1} ( t ) = S ( t ) + {N}_{1} ( t ) ,$$

$${U}_{2} ( t ) = S ( t ) + {N}_{2} ( t ) ,$$

where S(t) represents the ambient magnetic field signal, and Nᵢ(t), i=1,2 represents self-noise noise signals of sensors S₁ and SS′₁, respectively.

### Correlation Analysis:

A cross correlation analysis is performed on the measured magnetic signals. Assuming the self-noise signals N₁(t) and N₂(t) of the two magnetic sensors are uncorrelated, the cross-correlation function R₁₂(τ) is calculated as follows:

$$\begin{matrix}{R}_{12} ( τ ) = E [ {U}_{1} ( t ) {U}_{2} ( t - τ ) ] \\ = E [ ( S ( t ) + {N}_{1} ( t ) ) ( S ( t - τ ) + {N}_{2} ( t - τ ) ) ] \\ = {R}_{s} ( τ ) + {R}_{sn 1} ( τ ) + {R}_{sn 2} ( τ ) + {R}_{n 1 n 2} ( τ ) \\ ≅ {R}_{s} ( τ ) ,\end{matrix}$$

where U₁ and U₂ are the signals received by the magnetic sensors S₁ and S′₁, respectively; R₁₂is their cross-correlation function; Rₛ is the autocorrelation function of S(t); Rₛₙ₁ and Rₛₙ₂ are the cross correlation function between S(t) and N₁(t), and S(t) and N₂(t), respectively; and Rₙ₁ₙ₂ is the cross-correlation function between N₁(t) and N₂(t).

### Auto-Correlation Analysis:

It can be seen that the cross correlation function of the noise-containing signal Uᵢ(t), i=1,2 obtained in actual measurement is equal to the autocorrelation function of the ambient magnetic field signal S(t) without noise.

For the autocorrelation analysis of the measured magnetic field signal,

$$\begin{matrix}{R}_{11} ( τ ) = E [ {U}_{1} ( t ) {U}_{1} ( t - τ ) ] \\ = E [ ( S ( t ) + N 1 ( t ) ) ( S ( t - τ ) + {N}_{1} ( t - τ ) ) ] \\ = {R}_{s} ( τ ) + {R}_{sn 1} ( τ ) + {R}_{n 1 s} ( τ ) + {R}_{n 1} ( τ ) \\ ≅ {R}_{s} ( τ ) + {R}_{n 1} ( τ ) ,\end{matrix}$$

$$\begin{matrix}{R}_{22} ( τ ) = E [ {U}_{2} ( t ) {U}_{2} ( t - τ ) ] \\ = E [ ( S ( t ) + {N}_{2} ( t ) ) ( S ( t - τ ) + {N}_{2} ( t - τ ) ) ] \\ = {R}_{s} ( τ ) + {R}_{sn 2} ( τ ) + {R}_{n 2 s} ( τ ) + {R}_{n 2} ( τ ) \\ ≅ {R}_{s} ( τ ) + {R}_{n 2} ( τ ) ,\end{matrix}$$

where R₁₁ and R₂₂ are the auto-correlation functions of the signals from sensors S₁ and S′₁, respectively. Rₛₙ₁ and Rₙ₁ₛ both represent the cross correlation function between the ambient magnetic field signal S(t) and the self-noise signal N₁(t) of sensor S₁. Rₛₙ₂ and Rₙ₂ₛ both represent the cross correlation function of the ambient magnetic field signal S(t) and the self-noise signal N₂(t) of sensor S′₁. Rₙ₁ is the auto-correlation functions of the self-noise signals N₁(t) of sensor S₁. Rₙ₂ is the auto-correlation functions of the self-noise signals N₂(t). of sensor S′₁. Thus, the auto-correlation function of a measured signal equals the sum of the autocorrelation of the ambient signal and the autocorrelation of its own random noise.

### Noise Extraction:

Based on the above relationships, the autocorrelation function of each sensor's self-noise can be extracted by taking the difference between its auto-correlation function and the cross-correlation function:

$${R}_{n 1} ( τ ) ≅ {R}_{11} ( τ ) - {R}_{12} ( τ ) ,$$

$${R}_{n 2} ( τ ) ≅ {R}_{22} ( τ ) - {R}_{12} ( τ ) .$$

If S₁ and S′₁ are highly consistent, Rₙ₁(τ)≅Rₙ₂(τ). The measurement accuracy of the noise level can be further improved by averaging the results from multiple measurements to suppress random coherent noise:

$${R}_{n} ( τ ) = Mean \sum \frac{{R}_{n 1} ( τ ) + {R}_{n 2} ( τ )}{2}$$

In order to meet the requirements of test scheme and noise level of magnetic sensors, two magnetic sensors of the same type can be tested at the same time when the conversion coefficient and noise level of large-scale magnetic sensors are tested and calibrated.

Here, preferably, the sweep frequency alternating current source can be replaced by a combination of a pseudo-random signal generator and a power amplifier with a bandwidth satisfying the requirements.

The small-size magnetic sensor S₀ with the known conversion coefficient and satisfactory bandwidth can be replaced by commercial or independently developed reference magnetic sensors, such as magnetic bars, coils of small-size magnetic sensors, etc.

The shape of the calibration coil in the concentric loop configuration and the dipole loop configuration is not limited to a rectangle and a circle, and it suffices that the calibration coil generates a uniform magnetic field at the large-scale magnetic sensor to be calibrated.

### Embodiment

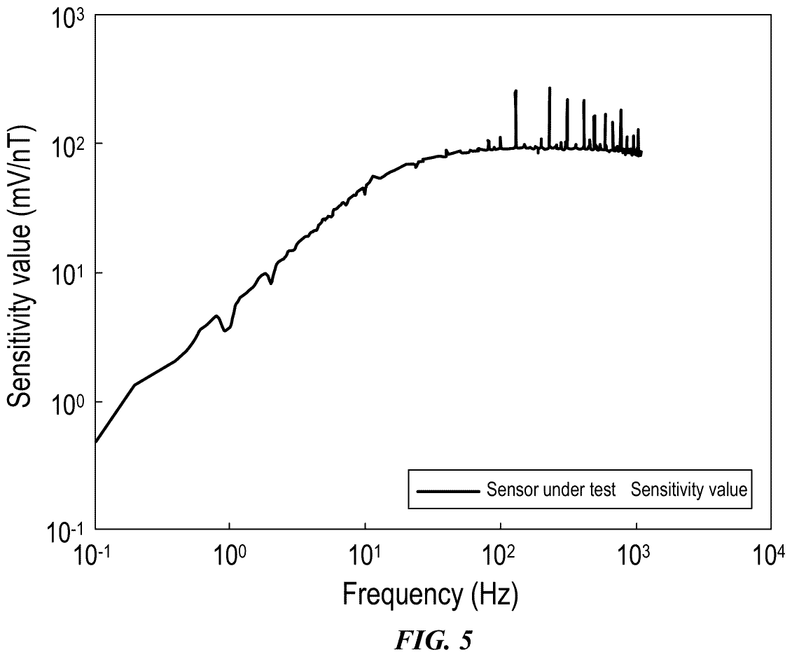

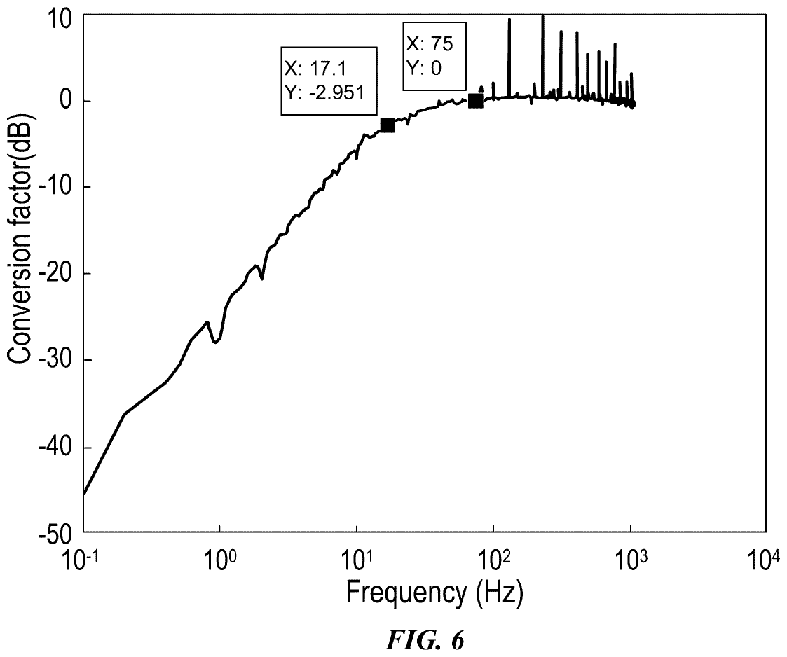

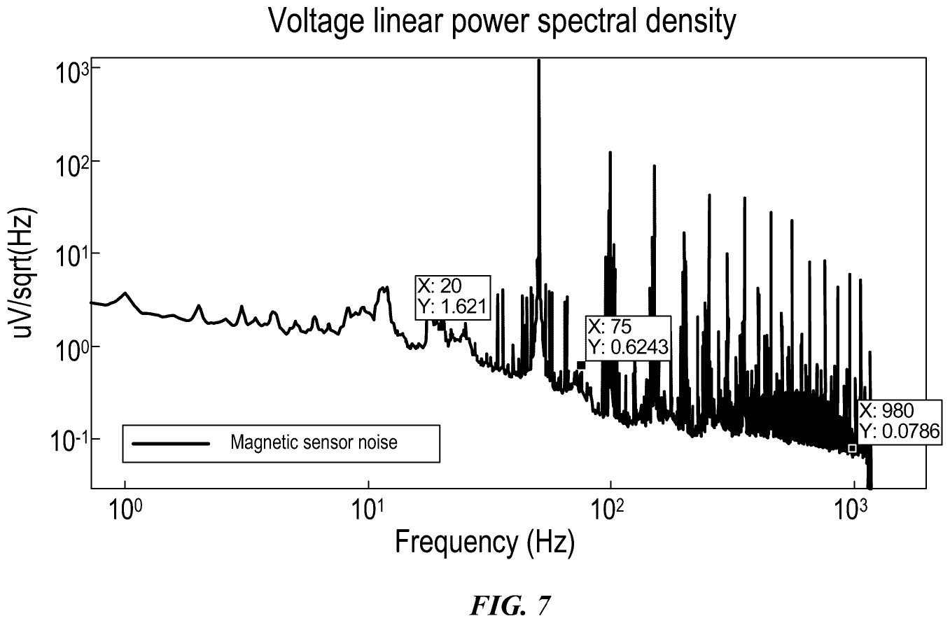

An embodiment applying the present method to calibrate an oversized magnetic sensor for an aero-magnetotelluric system is described. After selecting an appropriate test environment, the method outlined above was followed. The operational bandwidth test results of the magnetic sensor are shown in FIG. 5 and FIG. 6, indicating a sensor bandwidth of approximately 20 Hz-1000 Hz. The noise level test results of the magnetic sensor are shown in Table 1 and FIG. 7, showing a sensor noise level of approximately 7.6 fT/√Hz@75 Hz.

TABLE 1

Test result of noise level of magnetic sensor

| | Voltage power spectral | Magnetic field power |
|---|---|---|
| Frequencies | density | spectral density |
| f/Hz | U/(μV/√Hz) | B/(fT/√Hz) |
| 20 | 1.6210 | 25.78 |
| 75 | 0.6243 | 7.6 |
| 980 | 0.0768 | 1.0 |

In a second aspect, the present invention provides a system for calibrating an operational bandwidth and a noise level of a large-scale magnetic sensor, the system comprising:
a calibration coil, configured to be deployed in a test environment and to generate a magnetic field when driven by an alternating current source, wherein the calibration coil has a diameter typically ranging from 20 to 200 meters;
a multi-channel receiver; and
a processor, communicatively coupled to the multi-channel receiver and configured to:
(i) calibrate the operational bandwidth of the magnetic sensor under test based on voltage signals synchronously acquired by the multi-channel receiver from a reference magnetic sensor and the magnetic sensor under test when both are exposed to the magnetic field generated by the calibration coil; and
(ii) determine the noise level of the magnetic sensor under test by performing a correlation analysis on output signals synchronously acquired by the multi-channel receiver from the magnetic sensor under test and a second magnetic sensor of the same type when both are exposed to the magnetic field;
wherein the magnetic sensor under test is a large-scale magnetic sensor with a coil diameter not less than 2 meters.

In a third aspect, the present invention provides an electronic device, comprising:
one or more processors; and
a memory configured for storing one or more programs;
wherein the one or more programs, when executed by the one or more processors, cause the one or more processors to implement the method for calibrating the operational bandwidth and the noise level of the large-scale magnetic sensor according to any one of the preceding claims.

In a fourth aspect, the present invention provides a non-transitory computer-readable storage medium having stored thereon executable instructions which, when executed by a processor, cause the processor to implement the method for calibrating the operational bandwidth and the noise level of the large-scale magnetic sensor according to any one of the preceding claims.

The objective, technical solutions, and beneficial effects of the invention are further described in detail through the above specific embodiments. It should be understood that the above is only a specific embodiment of the invention, and is not used to limit the invention. Where within the spirit and principles of the invention, any modification, equivalent replacement, improvement, etc., shall be included in the scope of protection of the invention.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheetare incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for calibrating an operational bandwidth and a noise level of a large-scale magnetic sensor, the method comprising:
step 1, selecting a test environment and a test device configuration, and deploying a transmitting current coil as a calibration coil therein;
step 2, inputting an alternating current to the calibration coil to generate a magnetic field;, synchronously acquiring voltage signals from the reference magnetic sensor and the magnetic sensor under test via a multi-channel receiver; and calibrating the operational bandwidth of the magnetic sensor under test based on the voltage signals; and
step 3, inputting the alternating current to the calibration coil to generate a magnetic field;, synchronously acquiring output signals from the magnetic sensor under test and the second magnetic sensor of the same type via the multi-channel receiver; and performing a correlation analysis on the output signals to determine a noise level of the magnetic sensor under test;
wherein the magnetic sensor under test is a large-scale magnetic sensor with a coil diameter of not less than 2 meters.

2. The method according to claim 1, wherein:
the test environment provides a sufficient operating space; and
the calibration coil is a transmitting current coil with a diameter of 20-200 meters deployed on the ground.

3. The method according to claim 1, wherein step 1 further comprises selecting a test device configuration from a group consisting of a concentric loop configuration or a dipole loop configuration.

4. The method according to claim 1, wherein:
when the concentric loop configuration is selected, the method comprises concentrically and coaxially placing the magnetic sensor under test and the reference magnetic sensor, and concentrically and coaxially placing the calibration coil with the magnetic sensor under test;
when the dipole loop configuration is selected, the method comprises concentrically and coaxially placing the magnetic sensor under test and the reference magnetic sensor, and placing the calibration coil at a position greater than 50 meters away from the magnetic sensor under test;
the method further comprising:
inputting alternating currents of different frequencies by an alternating current generator into the calibration coil to generate a magnetic field signal;
synchronously acquiring the voltage signals from the reference magnetic sensor and the magnetic sensor under test using a dual-channel signal receiver;
calibrating a response of the magnetic sensor under test based on the voltage signals from the reference magnetic sensor to obtain conversion coefficients of the magnetic sensor under test; and
determining the operational bandwidth of the magnetic sensor under test based on the conversion coefficient acquired at different frequencies.

5. The method according to claim 4, wherein the voltage signals are obtained by converting the signal of the magnetic field generated in the space via the conversion coefficients of the reference magnetic sensor and the magnetic sensor under test.

6. The method according to claim 4, wherein the reference magnetic sensor has a known conversion coefficient, and an operational bandwidth of the reference magnetic sensor covers an operational bandwidth of the magnetic sensor under test.

7. The method according to claim 1, wherein step 3 comprises:
when the concentric loop configuration is selected, concentrically and coaxially placing the calibration coil, the magnetic sensor under test, and the second magnetic sensor of the same type, wherein the magnetic sensor under test and the second magnetic sensor of the same type are disposed in a parallel, vertically-spaced, and non-coplanar arrangement;
when the dipole loop configuration is selected, placing the calibration coil at a position greater than 50 meters away from the magnetic sensor under test, wherein the magnetic sensor under test and the second magnetic sensor of the same type are vertically positioned parallel and non-coplanar;
the method further comprising:
inputting alternating currents of different frequencies by an alternating current generator into the calibration coil to generate a magnetic field signal in the space;
synchronously acquiring the output signals of the second magnetic sensor of the same type and the magnetic sensor under test via the dual-channel signal receiver, wherein the output signals comprise an ambient magnetic field signal and respective self-noise signals of the second magnetic sensor of the same type and the magnetic sensor under test; and
performing the correlation analysis by:
(i) calculating an autocorrelation function (R₁₁) of the output signal from the magnetic sensor under test;
(ii) calculating an autocorrelation function (R₂₂) of the output signal from the second magnetic sensor of the same type;
(iii) calculating a cross-correlation function (R₁₂) between the output signals from the magnetic sensor under test and the second magnetic sensor;
(iv) obtaining an autocorrelation function of a self-noise signal of the magnetic sensor under test by calculating a difference between R₁₁ and R₂₂; and
(v) determining the noise level from the obtained autocorrelation function of the self-noise signal.

8. (canceled)

9. An electronic device, comprising:
one or more processors; and
a memory configured for storing one or more programs;
wherein one or more programs, when executed by the one or more processors, cause the one or more processors to implement the method for calibrating the operational bandwidth and the noise level of the large-scale magnetic sensor according to claim 1.

10. A non-transitory computer-readable storage medium, characterized by having stored thereon executable instructions which, when executed by a processor, cause the processor to implement the method for calibrating the operational bandwidth and the noise level of the large-scale magnetic sensor according to claim 1.

11-12. (canceled)

13. A device for calibrating an operational bandwidth and a noise level of a large-scale magnetic sensor, the device comprising:
an apparatus selection module configured to select a test environment and a test device type, and to deploy a transmitting current coil in the test environment as a calibration coil, wherein the test device type indicating placing a calibration coil and a magnetic sensor under test;
a first signal acquisition module configured to input an alternating current to the calibration coil to generate a magnetic field signal to affect a reference magnetic sensor and the magnetic sensor under test, synchronously acquire voltage signals of the reference magnetic sensor and the magnetic sensor under test by a multi-channel receiver, and calibrate an operational bandwidth of the magnetic sensor under test by the voltage signals; and
a second signal acquisition module configured to input the alternating current to the calibration coil to generate a magnetic field signal to affect a homogeneous magnetic sensor and the magnetic sensor under test, synchronously acquire output signals of the homogeneous magnetic sensor and the magnetic sensor under test by the multi-channel receiver, and perform correlation analysis to determine a noise level of the magnetic sensor under test;
wherein the magnetic sensor under test is a large-scale magnetic sensor, and the coil diameter of the large-scale magnetic sensor is not less than 2 meters.
